(19) United States
(12) Patent Application Publication
(10) Pub. No.: US 2009/0176377 A1
(43) Pub. Date: Jul. 9, 2009

(54) METHOD OF FORMING PATTERNS OF SEMICONDUCTOR DEVICE

(75) Inventor: Woo Yung JUNG, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/346,449

(22) Filed: Dec. 30, 2008

(30) Foreign Application Priority Data
Jan. 3, 2008 (KR) 10-2008-0000615

(51) Int. Cl. H01L 21/027

(52) U.S. Cl. 438/761; 257/E21.023

(57) ABSTRACT

The present invention relates to a method of forming patterns of a semiconductor device. In an aspect of the present invention, the method may include providing a semiconductor substrate, including a first area in which patterns are formed at a first interval and a second area formed wider than the first interval, forming an etch mask layer formed over the semiconductor substrate, forming photoresist patterns formed over the etch mask layer, wherein an auxiliary pattern is formed at an outermost area of the second area, forming first etch mask patterns by patterning the etch mask layer using the photoresist patterns and the auxiliary pattern, forming an auxiliary layer on the entire surface including the first etch mask patterns, forming a second etch mask pattern in concave portions of the auxiliary layer, and removing the auxiliary layer that is exposed.

### CROSS-REFERENCES TO RELATED APPLICATION

The present application claims priority to Korean patent application number 10-2008-0000615, filed on Jan. 3, 2008, which is incorporated by reference in its entirety.

### BACKGROUND OF THE INVENTION

The present invention relates to a method of forming patterns of a semiconductor device and, more particularly, to a method of forming patterns of a semiconductor device, which is capable of forming micro patterns having a pitch smaller than resolving power of a exposure apparatus.

A minimum pitch of patterns used in a lithography process, which uses light, of a manufacturing process of semiconductor device depends on the wavelength of exposure light used in an exposure apparatus. Accordingly, in order to form patterns having a smaller pitch in a current situation in which semiconductor devices are high integrated, light having a wavelength shorter than that of light that is used currently must be used. To this end, it may be preferred that X ray or E-beam be used, but the use of X ray or E-beam is still in an experimental stage due to technical problems, productivity, and so on. Thus, a Dual Exposure and Etch Technology (DEET) was proposed.

FIGS. 1A to 1C are sectional views showing a DEET. As shown in FIG. 1A, a first photoresist PR1 is coated over a semiconductor substrate 10 having a target etching layer 11, and is then patterned using exposure and development processes. The target etching layer 11 is etched using the patterned first photoresist PR1 as a mask. Each of the etched target etching layers 11 has a line width of 150 nm, and a space width between the etched target etching layers 11 is 50 nm.

Next, the first photoresist PR1 is removed, and a second photoresist PR2 is coated on the entire surface. As shown in FIG. 1B, the second photoresist PR2 is patterned using exposure and development processes so that part of the target etching layer 11 is exposed.

Next, as shown in FIG. 1C, the target etching layer 11 is etched again using the patterned second photoresist PR2 as a mask, thus forming final patterns. Each of the final patterns has a line width of 50 nm, and a space width between the final patterns is 50 nm. The second photoresist PR2 is then removed.

In the above-described DEET, when an exposure process is performed on the second photoresist PR2, overlay accuracy greatly depends on Critical Dimension (CD) variation of final patterns. Actually, overlay accuracy of exposure equipment is difficult to control less than 10 nm, which makes it difficult to reduce CD variation of final patterns. It is also difficult to control Optical Proximity Correction (OPC) due to circuit separation depending on dual exposure.

### BRIEF SUMMARY OF THE INVENTION

The present invention is directed towards a method of forming patterns of a semiconductor device, which is capable of forming patterns having a pitch smaller than resolution of exposure equipment and also providing a stable pattern formation process, in such a manner that, in a pattern formation process of a semiconductor device, first etch mask patterns are formed using a photoresist pattern by an exposure process, an isolation layer is formed on the entire surface including the first etch mask patterns, a second etch mask patterns are formed between space between the first etch mask patterns, micro patterns are formed by etching the exposed isolation layer, and auxiliary patterns are formed at an outer area in order to secure the thickness of the second etch mask pattern in an area in which a pitch of patterns is large.

In a method of forming patterns of a semiconductor device according to an aspect of the present invention, first, a semiconductor substrate, including a first area in which patterns are formed at a first interval and a second area formed wider than the first interval, is provided. An etch mask layer is formed over the semiconductor substrate. Photoresist patterns are formed over the etch mask layer, wherein an auxiliary pattern is formed at an outermost area of the second area. First etch mask patterns are formed by patterning the etch mask layer using the photoresist patterns and the auxiliary pattern. An auxiliary layer is formed on the entire surface including the first etch mask patterns. A second etch mask pattern is formed in concave portions of the auxiliary layer. The auxiliary layer that is exposed is then removed.

The formation of the second etch mask pattern may include coating a photoresist layer on the entire surface including the auxiliary layer, and performing exposure and development on the photoresist layer formed in the second area so that the photoresist layer remains in the concave portions of the auxiliary layer between the auxiliary pattern and the photoresist patterns.

The photoresist layer may be formed to a thickness thicker than that of the second etch mask pattern in space between the auxiliary pattern and the photoresist patterns by the auxiliary pattern.

The photoresist layer may be formed from a photoresist layer including Si.

Before the etch mask layer is formed, a target etching layer is formed on the semiconductor substrate.

The first etch mask layer may be formed from a MFHM (BARC including Si) layer.

The first area is an area in which gate lines of the semiconductor device are formed, and the second area is an area in which interconnection portions of the gate lines are formed. A pitch of the photoresist patterns is twice a pitch of the first and second etch mask patterns.

In a method of forming patterns of a semiconductor device according to another aspect of the present invention, first, a target etching layer, a first etch mask layer, and a BARC layer are formed over a semiconductor substrate. Photoresist patterns are formed on the BARC layer, wherein an auxiliary pattern is formed at an outermost area of the photoresist patterns. First etch mask patterns are formed by patterning the first etch mask layer using the photoresist patterns and the auxiliary pattern. An auxiliary layer is formed on the entire surface including the first etch mask patterns. A second etch mask layer is formed on the entire surface including the auxiliary layer, wherein the second etch mask layer remains to a specific thickness or more in space between the photoresist patterns and the auxiliary pattern. The second etch mask layer is made to remain in concave portions of the auxiliary layer, thus forming a second etch mask pattern. The auxiliary layer that is exposed is then removed.

### BRIEF DESCRIPTION OF THE DRAWINGS

FIGS. 1A is to 1C are sectional views showing a DEET; and

FIGS. 2A to 8B are sectional views showing a method of forming patterns of a semiconductor device according to an embodiment of the present invention.

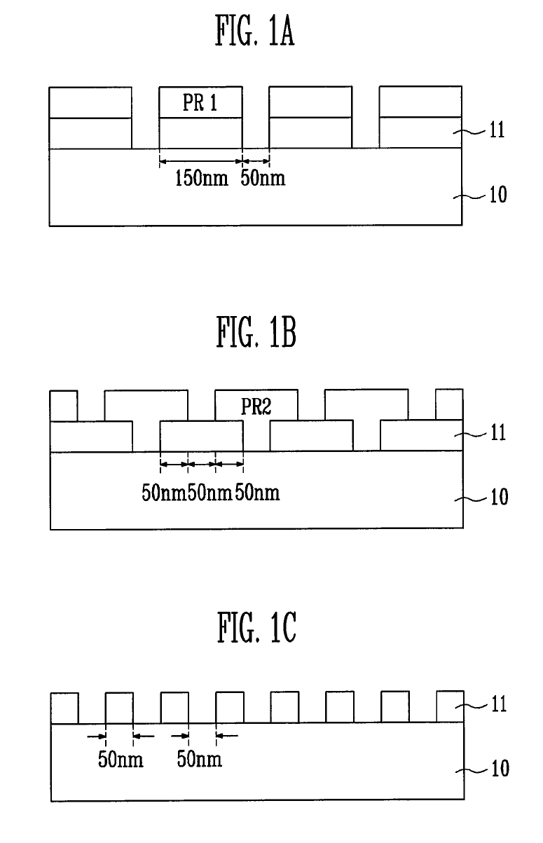

### DESCRIPTION OF SPECIFIC EMBODIMENT

Hereinafter, the present invention will be described in detail in connection with a specific embodiment with reference to the accompanying drawings. The present embodiment is provided to complete the disclosure of the present invention and to allow those having ordinary skill in the art to understand the scope of the present invention. When it is said that any part, such as a layer, film, area, or plate, is positioned on another part, it means the part is directly on the other part or above the other part with at least one intermediate part. To clarify multiple layers and regions, the thickness of the layers is enlarged in the drawings.

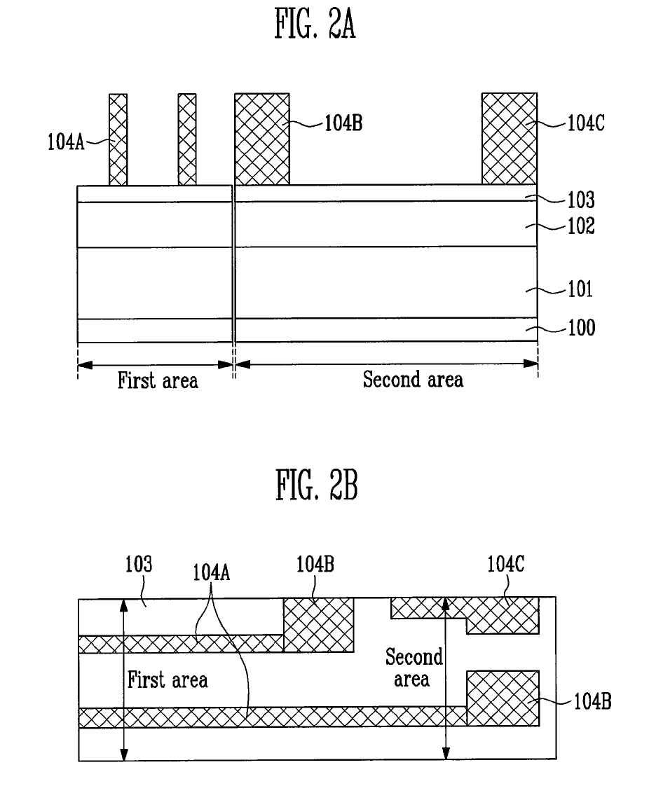

FIGS. 2A to 8B are sectional views and plan views of semiconductor devices according to an embodiment of the present invention.

The present invention is described below in connection with, for example, an embodiment in which gate lines and gate line interconnection portions of a semiconductor device are patterned. However, it should be understood that the present invention is not limited to the above embodiment, but may be applied to other processes of forming patterns of a semiconductor device.

Referring to FIGS. 2A and 2B, a target etching layer 101, a first etch mask layer 102, a Bottom Anti-Reflection Coating (BARC) layer 103, and photoresist patterns 104A, 104B, and 104C are formed over a semiconductor substrate 100 including a first area (gate line area) and a second area (gate line interconnection portion). It may be preferred that a pitch of the photoresist patterns 104A be twice greater than that of patterns to be formed finally. The photoresist pattern 104B is a pattern for forming an interconnection portion of gate lines, and is preferably formed to have a width greater than that of each of the photoresist patterns 104A for the purpose of process margin. The photoresist pattern 104C is spaced apart from the photoresist pattern 104B at a specific interval, and is preferably formed at an outer area of an interconnection portion of gate lines that will be formed finally.

The target etching layer 101 may be preferably formed from Spin On Carbon (SOC). The target etching layer 101 may be preferably formed to a thickness of 1000 Å to 3000 Å. After the target etching layer 101 is formed, it may be preferred that a bake process be performed in a temperature range of 150° C. to 300° C. for 45 seconds to 120 seconds, and then cooled in a plate having a temperature of 20° C. to 30° C. for 45 seconds to 120 seconds.

The first etch mask layer 102 is preferably formed from a Multi-Function Hard Mask (MFHM) (BARC including Si) layer. The MFHM layer includes Si, and therefore, at the time of a subsequent etch process, there occurs a difference in the etch rate between the MFHM layer and the target etching layer 101, formed from a SOC layer. Since the MFHM layer is transparent, an additional key-open process for pattern alignment is omitted in a process of forming the photoresist patterns 104.

The first etch mask layer 102 is preferably formed to a thickness of 200 Å to 1000 Å. After the first etch mask layer 102 is formed, it may be preferred that a bake process be performed in a temperature of 150° C. to 300° C. for 45 seconds to 120 seconds, and then cooled in a plate having a temperature of 20° C. to 30° C. for 45 seconds to 120 seconds.

The BARC layer 103 is preferably formed to a thickness of 200 Å to 1000 Å. After the BARC layer 103 is formed, it may be preferred that a bake process be performed in a temperature range of 150° C. to 300° C. for 45 seconds to 120 seconds, and then cooled in a plate having a temperature of 20° C. to 30° C. for 45 seconds to 120 seconds.

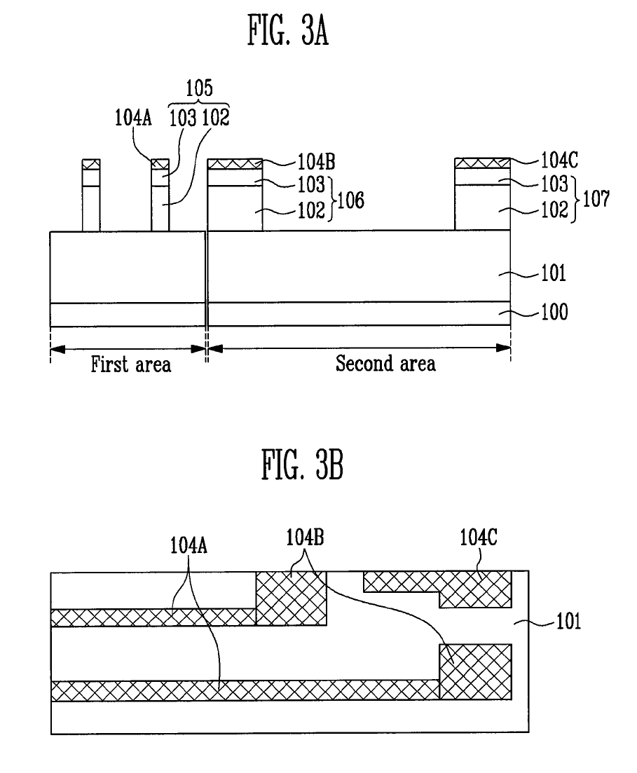

Referring to FIGS. 3A and 3B, the BARC layer 103 and the first etch mask layer 102 are patterned by performing an etching process using the photoresist patterns 104A, 104B, and 104C as an etch mask, thus forming first etch mask patterns 105, 106, and 107. The photoresist patterns 104A, 104B, 104C may remain on the first etch mask patterns 105, 106, and 107 to a certain thickness.

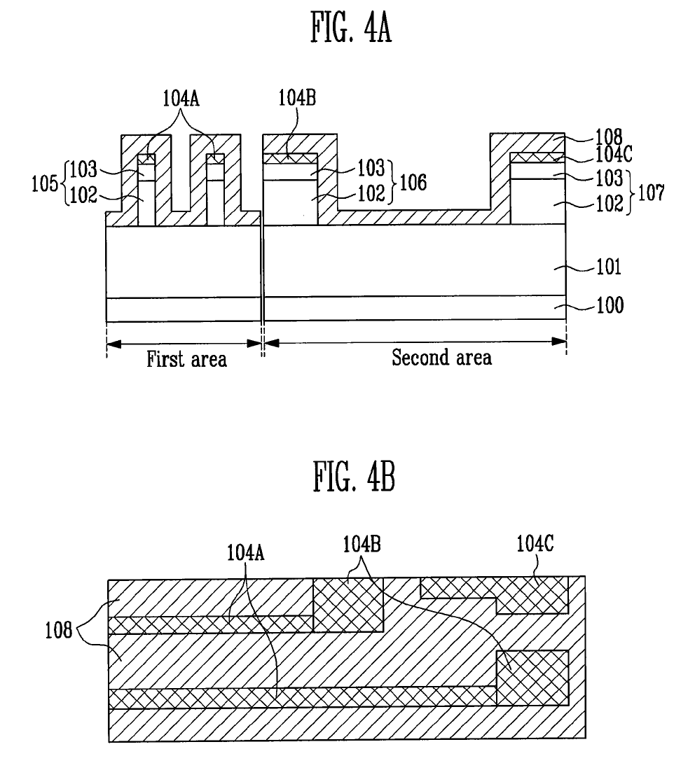

Referring to FIGS. 4A and 4B, an auxiliary layer 108 is formed on the entire surface including the first etch mask patterns 105, 106, and 107. More specifically, it may be preferred that the auxiliary layer 108 be formed on sidewalls and top surfaces of the first etch mask patterns 105, 106, and 107, but space between the first etch mask patterns 105 and 106 is comparable to a pitch of the first etch mask patterns 105 and 106. The auxiliary layer 108 is preferably formed from a carbon layer. Referring to FIG. 4b, although the auxiliary layer 108 is formed on the entire surface, the photoresist patterns 104A, 104B and 104C are shown to appear in order to help easy understanding of the structure.

Referring to FIG. 5, a second etch mask layer 109 is formed on the entire surface including the auxiliary layer 108. The second etch mask layer 109 is formed by coating a photoresist layer including Si. The photoresist layer is formed using a spin-coating method in such a way as to interval fill concave portions of the auxiliary layer 108. In an outer area A of the first etch mask pattern 106, the second etch mask layer 109 is formed to have a specific height or more (preferably, a height that remains at the time of a subsequent etch process) by the first etch mask pattern 107. Accordingly, even if the second etch mask layer 109 with good fluidity is formed using a spin-coating method, the first etch mask pattern 107 functions to prevent the second etch mask layer 109 from flowing into the edge portion of a wafer. Consequently, the second etch mask layer 109 can have a specific height or more (preferably, a thickness greater than a thickness of the second etch mask patterns that is subsequently formed).

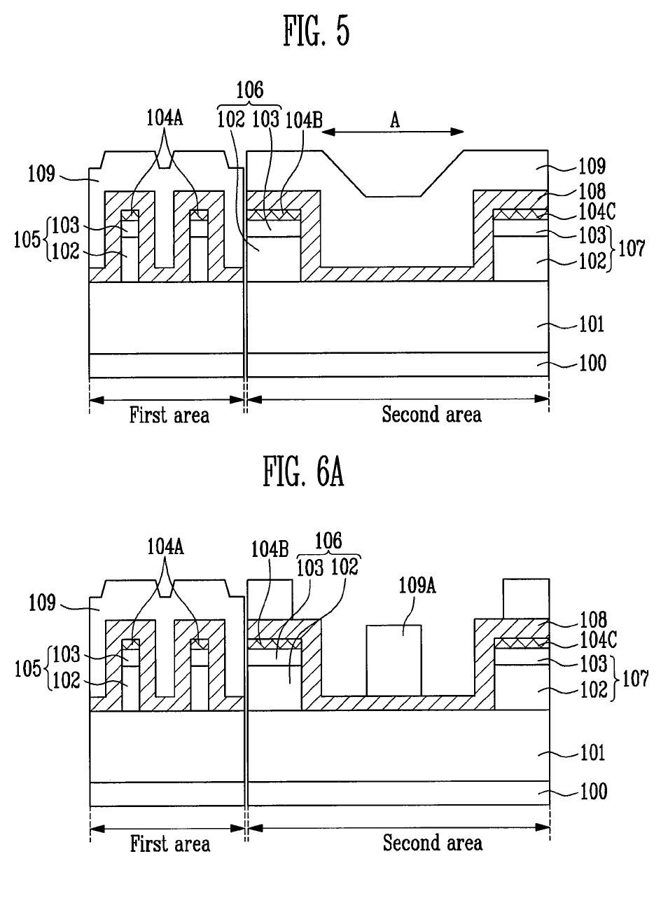

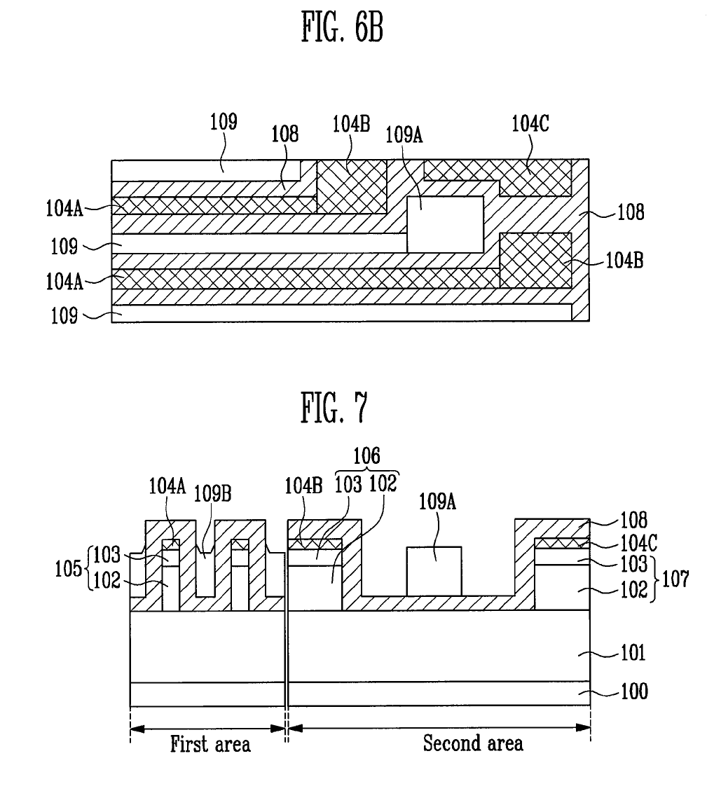

Referring to FIGS. 6A and 6B, the second etch mask layer in the space between the first etch mask patterns 106 and 107 are patterned using exposure and development processes, thereby forming a second etch mask pattern 109A.

Referring to FIG. 7, the photoresist layer formed on the protruding auxiliary layer 108 of the first area is removed using an etching process, and the photoresist layer remains in the concave portions of the auxiliary layer 108, thus forming a second etch mask pattern 109B. The second etch mask pattern 109A of the second area has a thickness sufficient for a subsequent etching process although a top surface of the second etch mask pattern 109A has a reduced height due to etching at the time of an etch process.

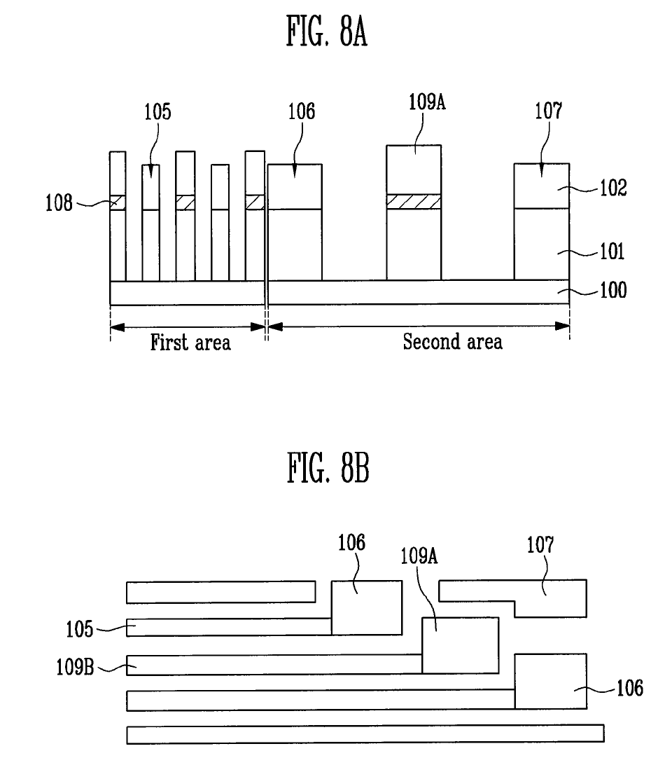

Referring to FIGS. 8A and 8B, the exposed auxiliary layer is etched in order to expose the target etching layer 101. Next, the exposed target etching layer 101 is etched in order to form patterns (for example, hard mask patterns) for forming gate lines and interconnection portions of a semiconductor device. The BARC layer 103 may remove when the auxiliary layer 108 is etched

The embodiment disclosed herein has been proposed to allow a person skilled in the art to easily implement the present invention, and the person skilled in the part may implement the present invention in various ways. Therefore, the scope of the present invention is not limited by or to the embodiment as described above, and should be construed to be defined only by the appended claims and their equivalents.

What is claimed is:

1. A method of forming patterns of a semiconductor device, the method comprising:
providing a semiconductor substrate, including a first area in which patterns are formed at a first interval and a second area formed wider than the first interval;
forming an etch mask layer over the semiconductor substrate;
forming photoresist patterns over the etch mask layer, wherein an auxiliary pattern is formed at an outermost area of the second area;
forming first etch mask patterns by patterning the etch mask layer using the photoresist patterns and the auxiliary pattern;
forming an auxiliary layer on the entire surface including the first etch mask patterns;
forming a second etch mask pattern in concave portions of the auxiliary layer; and
removing the auxiliary layer that is exposed.

2. The method of claim 1, wherein the formation of the second etch mask pattern comprises:
coating a photoresist layer on the entire surface including the auxiliary layer; and
performing exposure and development on the photoresist layer formed in the second area so that the photoresist layer remains in the concave portions of the auxiliary layer between the auxiliary pattern and the photoresist patterns.

3. The method of claim 2, wherein the photoresist layer is formed to a thickness thicker than that of the second etch mask pattern in space between the auxiliary pattern and the photoresist patterns by the auxiliary pattern.

4. The method of claim 2, wherein the photoresist layer is formed from a photoresist layer including Si.

5. The method of claim 1, wherein, before the etch mask layer is formed, a target etching layer is formed on the semiconductor substrate.

6. The method of claim 1, wherein the first etch mask layer is formed from a MFHM (BARC including Si) layer.

7. The method of claim 1, wherein:
the first area is an area in which gate lines of the semiconductor device are formed, and
the second area is an area in which interconnection portions of the gate lines are formed.

8. The method of claim 1, wherein a pitch of the photoresist patterns is twice a pitch of the first and second etch mask patterns.

9. A method of forming patterns of a semiconductor device, the method comprising:
forming a target etching layer, a first etch mask layer, and a BARC layer over a semiconductor substrate;
forming photoresist patterns on the BARC layer, wherein an auxiliary pattern is formed at an outermost area of the photoresist patterns;
forming first etch mask patterns by patterning the first etch mask layer using the photoresist patterns and the auxiliary pattern;
forming an auxiliary layer on the entire surface including the first etch mask patterns;
forming a second etch mask layer on the entire surface including the auxiliary layer, wherein the second etch mask layer remains to a specific thickness or more in space between the photoresist patterns and the auxiliary pattern;
allowing the second etch mask layer to remain in concave portions of the auxiliary layer, thus forming a second etch mask pattern; and
removing the auxiliary layer that is exposed.

10. The method of claim 9, wherein the second etch mask layer is formed to a thickness greater than that of the second etch mask pattern in the space between the photoresist patterns and the auxiliary pattern.

11. The method of claim 9, wherein the second etch mask layer is formed from a photoresist layer including Si.

12. The method of claim 9, wherein the target etching layer is formed from a SOC layer.

13. The method of claim 9, wherein the first etch mask layer is formed from a MFHM (BARC including Si) layer.
